(19) United States
(12) Patent Application Publication
(10) Pub. No.: US 2026/0333615 A1
(43) Pub. Date: Oct. 22, 2026

(54) CENTRIFUGAL FAN WITH NON-LINEAR AIR FLOW

(71) Applicant: AMD Design, LLC, Wilmington, DE (US)

(72) Inventor: Darrin Troy VALLIS, Austin, TX (US)

(73) Assignee: AMD Design, LLC, Wilmington, DE (US)

(21) Appl. No.: 19/184,195

(22) Filed: Apr. 21, 2025

(51) Int. Cl. H05K 7/20; G10K 11/162

(52) U.S. Cl. CPC H05K 7/20145; G10K 11/162; H05K 7/20172; H05K 7/20718

(57) ABSTRACT

A centrifugal fan system for exhausting air from a server is described herein. The centrifugal fan system includes a centrifugal fan assembly and a housing. The housing at least partially surrounds the centrifugal fan assembly, forms a fan air duct in airflow communication with the centrifugal fan assembly and forms an air outlet duct. The air outflow duct is in airflow communication with the fan air duct and includes an air exhaust outlet that is configured to exhaust air from the centrifugal fan system. The air outflow duct is configured such that airflow from the fan air duct to the air exhaust outlet is non-linear.

### FIELD

This disclosure is directed to centrifugal fans, such as centrifugal fans used in servers.

### BACKGROUND

A server often employs one or more fans which circulate and remove hot air from the server. While axial and centrifugal fans may be implemented, centrifugal fans may offer increased energy efficiency. Although they may be more energy efficient, centrifugal fans also produce noise (e.g., from the fan blades, motor, etc.). Outside of human discomfort and safety, the noise generated by centrifugal fans can negatively effect components of the server. For example, read and/or write performance of many hard drives can be effected by noise from centrifugal fans. The problem may be compounded when multiple servers are collocated (e.g., within a rack, server room, server farm, etc.).

### SUMMARY

A centrifugal fan system for exhausting air from a server is described herein. The centrifugal fan system includes a centrifugal fan assembly, a fan housing including a fan air duct disposed in airflow communication with the centrifugal fan assembly, and an air outlet housing including an air outlet duct disposed in airflow communication with the fan air duct and including an air exhaust outlet that is configured to exhaust air from the server. The air outlet housing is configured such that airflow from the fan air duct to the air exhaust outlet via the air outlet duct is non-linear.

A server is also described herein. The server includes the centrifugal fan system above.

The foregoing summary is illustrative only and is not intended to be in any way limiting. In addition to the illustrative aspects, embodiments, and features described above, further aspects, embodiments, and features will become apparent by reference to the drawings and the following detailed description. In the drawings, like reference numbers indicate identical or functionally similar elements.

### BRIEF DESCRIPTION OF THE DRAWINGS

FIG. 1 illustrates a perspective view of a centrifugal fan system in accordance with this disclosure.

FIG. 2 illustrates a cross-sectional view of the centrifugal fan system of FIG. 1 taken along cross section A-A of FIG. 3 in accordance with this disclosure.

FIG. 3 illustrates a front view of the centrifugal fan system of FIG. 1 in accordance with this disclosure.

FIG. 4 illustrates a side view of the centrifugal fan system of FIG. 1 in accordance with this disclosure.

FIG. 5 illustrates a side view of a server including multiple centrifugal fan systems of FIG. 1 in accordance with this disclosure.

FIG. 6 illustrates a perspective view of the server of FIG. 5 in accordance with this disclosure.

### DETAILED DESCRIPTION

In a centrifugal fan system for a server employing fans (e.g., axial or centrifugal fans or blowers), fan blades of the fans may be directly exposed to the influent and effluent flows (e.g., the outlet). Because of exposure, any noise generated by the motor and motions of the fan blades may travel with or against the air flow directly out of the fan and expose circuitry of the server to additional noise. Such additional noise may cause a detrimental impact on read, write or other operations of servers in densely packed server systems.

A centrifugal fan system for exhausting air from a server is described herein. The centrifugal fan system includes a centrifugal fan assembly and a housing. The housing at least partially surrounds the centrifugal fan assembly, forms a fan air duct in airflow communication with the centrifugal fan assembly and forms an air outlet duct. The air outflow duct is in airflow communication with the fan air duct and includes an air exhaust outlet that is configured to exhaust air from the centrifugal fan system. The air outflow duct is configured such that airflow from the fan air duct to the air exhaust outlet is non-linear. The air outflow duct may also include an acoustic material that is configured to mitigate noise generated by the centrifugal fan assembly.

By utilizing an air outflow duct that provides non-linear airflow from the fan assembly to the air exhaust outlet, the outflow of acoustic noise from the centrifugal fan system via the air exhaust outlet is reduced. In addition, the use of an acoustic material that absorbs or mitigates the noise traveling out of the air outflow duct further reduces the outflow of acoustic noise. In this manner, the impact of acoustic noise generated by the centrifugal fan system on read, write or other operations of servers in a densely packed server system may be mitigated.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

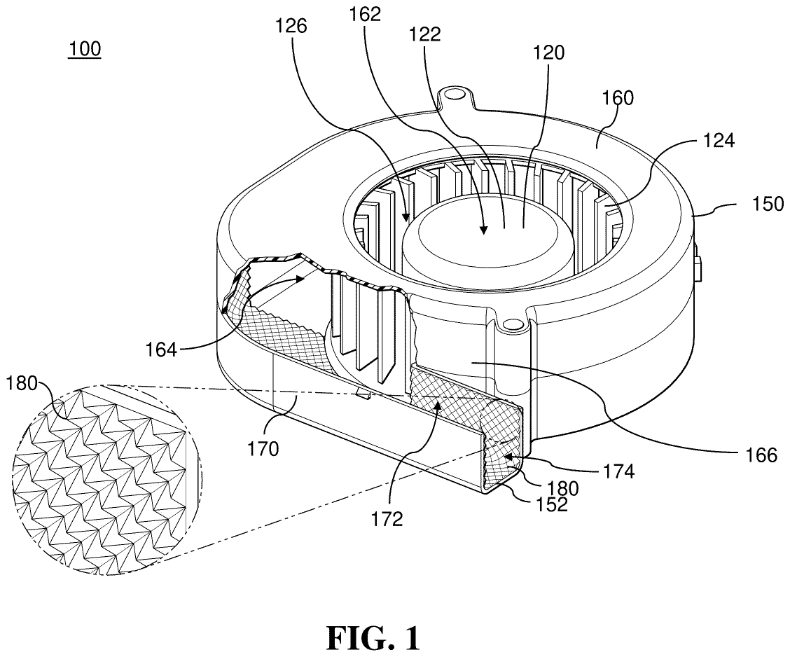

With reference to FIGS. 1-6, described herein is a centrifugal fan system 100 for exhausting hot air from a server. The centrifugal fan system 100 may be a centrifugal blower. Centrifugal fan system 100 comprises a centrifugal fan assembly 120 and chassis 150.

Centrifugal fan assembly 120 comprises a motor 122, a plurality of fins 124, and an intake 126. In some embodiments, centrifugal fan assembly 120 may comprise a centrifugal fan for exhausting air from a server. In other embodiments, other types of fans may alternatively be utilized.

Chassis 150 comprises a fan housing 160 that is configured to receive and secure centrifugal fan assembly 120. Fan housing 160 comprises an intake opening 162 that is aligned with intake 126 of centrifugal fan assembly 120 and a fan air duct 164 that is in airflow communication with fins 124 such that when motor 122 causes fins 124 to rotate about an axis of centrifugal fan assembly 120, air is drawn into centrifugal fan assembly 120 through intake 126 of centrifugal fan assembly 120 from an exterior of fan housing 160 via intake opening 162 and driven out of centrifugal fan assembly 120 into fan air duct 164 by fins 124.

Chassis 150 also comprises an air outlet housing 170 having an air outlet duct 172 and an air exhaust outlet 174 that are in airflow communication with fan air duct 164. In this configuration, the air outlet housing 170 prevents a direct acoustic path from the fins 124 to the space outside of the chassis 150. Accordingly, sound generated by the fins 124 contained in the airflow must pass over, by, or otherwise about, the acoustic material 180 in the air outlet housing 170, air outlet duct 172, and an air exhaust outlet 174.

In some embodiments, fan housing 160 and air outlet housing 170 may comprise separate components that are removably or fixedly attached to one another. In other embodiments, fan housing 160 and air outlet housing 170 may be formed as a single component.

When centrifugal fan assembly 120 is activated, fins 124 are configured to drive airflow from centrifugal fan assembly 120 through fan air duct 164 into air outlet duct 172 and out of air exhaust outlet 174.

Air outlet housing 170 is configured to guide airflow from fan air duct 164 to air exhaust outlet 174 in a manner that reduces or inhibits the exposure of noise from centrifugal fan assembly 120 to an exterior of centrifugal fan system 100, e.g., through air exhaust outlet 174, thereby reducing the effect of noise generated by centrifugal fan assembly 120 on the surrounding server environment.

In an embodiment, air outlet housing 170 is designed such that air and noise flow from centrifugal fan assembly 120 travels along a non-linear pathway from centrifugal fan assembly 120 to air exhaust outlet 174. For example, in some embodiments, air exhaust outlet 174 may be around a corner or otherwise located such that there is no line of sight, linear pathway, or axis of airflow available directly between the components of centrifugal fan assembly 120 and air exhaust outlet 174.

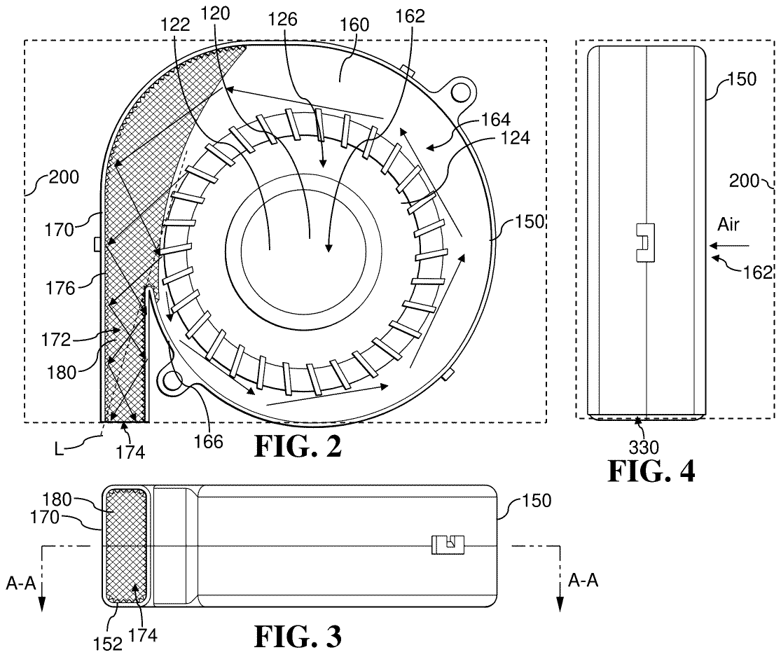

For example, arrows showing an example airflow are depicted in FIG. 2, where airflow travels through fan air duct 164, e.g., in a counterclockwise direction, and enters air outlet duct 172. Air flow may alternatively travel in a clockwise direction in some embodiments. As can be seen in FIG. 2, the air and attendant noise does not have a straight linear path through air outlet duct 172 from centrifugal fan assembly 120 or fan air duct 164. Instead, the air and attendant noise will impact against at least one sidewall 176 of air outlet duct 172 before exiting through air exhaust outlet 174. In some embodiments, air outlet duct 172 extends alongside an exterior wall 166 of fan housing 160 such that a portion of fan housing 160 is disposed between fins 124 of centrifugal fan assembly 120 and air exhaust outlet 174, e.g., as illustrated by dashed line L in FIG. 2.

In this manner, noise generated by centrifugal fan assembly 120 is inhibited from directly traveling out of air exhaust outlet 174 from centrifugal fan assembly 120 in a linear fashion, thereby reducing exhaust of at least some of the noise generated by centrifugal fan assembly 120 from air exhaust outlet 174.

In some embodiments, interior surfaces 152 of chassis 150 may comprise an acoustic material 180 that is configured to absorb, attenuate, reduce or otherwise modify any noise generated by centrifugal fan assembly 120 or other components of centrifugal fan system 100. For example, in some embodiments, acoustic material 180 may comprise a sound absorbing material such as, e.g., a foam, 3D printed acoustic metamaterial, acoustic absorption fiber, paint, layer or any other sound absorbing material, that is configured to inhibit the transfer of noise from centrifugal fan assembly 120 out of centrifugal fan system 100. Acoustic material 180 may be applied to interior surfaces 152 of chassis 150 including, e.g., sidewalls 176 of air outlet housing 170, walls of fan housing 160 or both.

For example, with reference to FIGS. 2 and 3, acoustic material 180 may comprise foam paneling having sound absorbing or diffracting shapes such as those often utilized in recording studios to absorb, redirect, or attenuate the sound generated by centrifugal fan assembly 120 and inhibit the sound from exiting through air exhaust outlet 174. In some embodiments, for example, the foam paneling may comprise polyurethane, melamine or other types of foam that are configured to absorb a range of frequencies.

In some embodiments, acoustic material 180 may comprise dense fiberglass or mineral wool that may also or alternatively be utilized for broad-range sound absorption.

Corners or other locations within chassis 150 may comprise bass traps or other components that are configured to target low-frequency sounds generated by centrifugal fan assembly 120.

Other materials may also or alternatively be utilized depending on the frequencies that need to be inhibited.

The acoustic material 180 may comprise a variety of acoustic shapes including, e.g., pyramid, wedge, and egg-crate shapes or any other shape providing desired acoustic properties. An example acoustic material 180 is shown in the expanded view of FIG. 1.

By employing acoustic material 180 in conjunction with the air flow path shown in FIG. 2 where air flow from fan air duct 164 will impact at least one sidewall 176 of air outlet duct 172 before exiting through air exhaust outlet 174, noise output from centrifugal fan system 100 via air exhaust outlet 174 may be significantly inhibited, reduced or even eliminated such that the impact of noise from centrifugal fan system 100 on a surrounding dense server environment is reduced or eliminated.

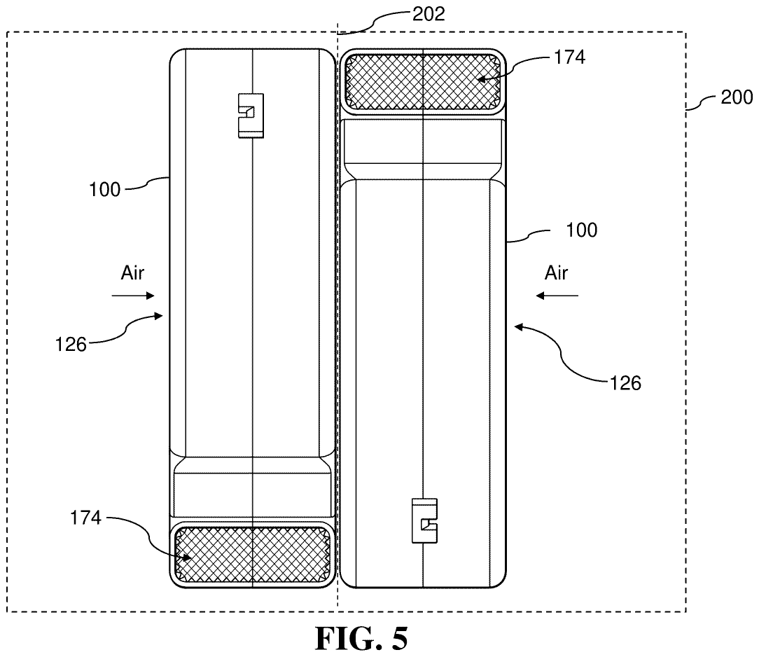

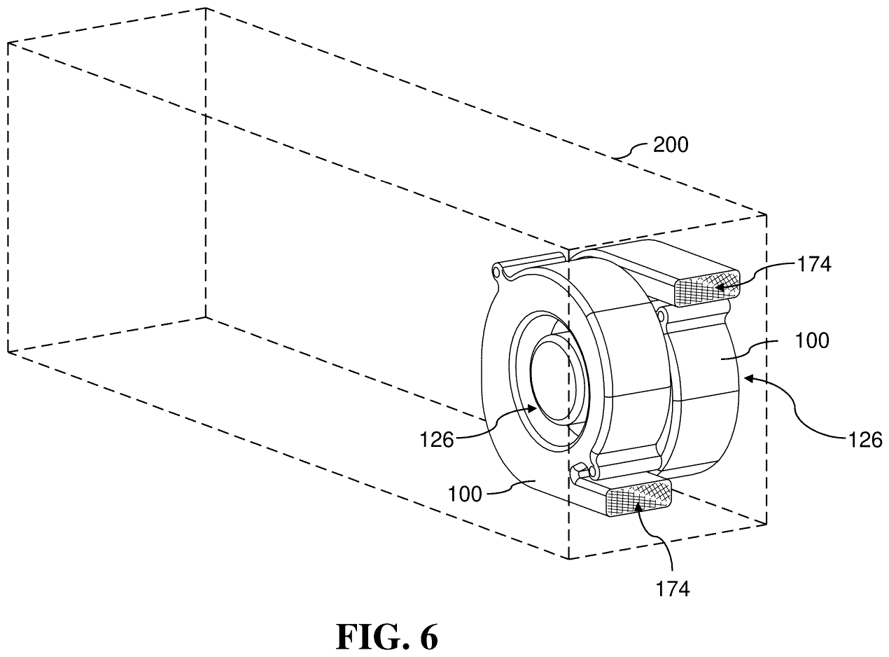

With reference to FIGS. 5 and 6, in some embodiments, multiple centrifugal fan system 100 may be stacked together in a server 200 to provide a compact form factor for the exhaust of air from server 200. For example, as shown in FIGS. 5 and 6, two centrifugal fan systems 100 may be stacked such that intakes 126 of centrifugal fan assemblies 120 are on opposite sides of a stacking plane 202 while the air exhaust outlets 174 of each centrifugal fan system 100 exhaust in the same direction, e.g., in a direction parallel to the stacking plane 202 in an embodiment.

With reference to FIGS. 1-6, an example process of operation for centrifugal fan system 100 will now be described.

First, server 200 activates centrifugal fan assembly 120 to exhaust air out of server 200.

Centrifugal fan assembly 120 draws air from within server 200 into intake 126 via intake opening 162 of fan housing 160 and drives the air into fan air duct 164.

The air flows out of fan air duct 164 into air outlet duct 172 of air outlet housing 170, engaging against at least one sidewall 176 of air outlet housing 170. In a case where acoustic material 180 is present, acoustic material may absorb, modify or otherwise adjust any acoustic properties in the air flow such as, e.g., noise being carried by the airflow from centrifugal fan assembly 120. For example, acoustic material 180 may absorb some or all noise being carried by the airflow.

The air continues along air outlet duct 172, contacting additional sidewalls 176 if needed until exiting via air exhaust outlet 174 with any noise having been inhibited, reduced, attenuated or modified in a manner to reduce the acoustic impact on the operations of nearby servers.

### EXAMPLES

Example 1: A centrifugal fan system for a server, the centrifugal fan system comprising: a centrifugal fan assembly; and a housing: at least partially surrounding the centrifugal fan assembly; forming a fan air duct in airflow communication with the centrifugal fan assembly; and forming an air outlet duct: in airflow communication with the fan air duct; including an air exhaust outlet configured to exhaust air from the centrifugal fan system; and configured such that airflow from the fan air duct to the air exhaust outlet is non-linear.
Example 2: The centrifugal fan system of example 1, wherein a sidewall of the air outlet duct includes an acoustic material configured to mitigate noise generated by the centrifugal fan assembly.
Example 3: The centrifugal fan system of example 2, wherein the acoustic material is configured to mitigate noise having one or more frequencies.
Example 4: The centrifugal fan system of example 2 or 3, wherein the acoustic material includes: a foam material, a fiber material, or a paint material.
Example 5: The centrifugal fan system of any of examples 2-4, wherein at least a portion of the acoustic material is formed via 3D printing.
Example 6: The centrifugal fan system of any of examples 2-5, wherein at least a portion of the acoustic material is formed as: a pyramid shape, a wedge shape, or an egg-crate shape.
Example 7: The centrifugal fan system of any preceding example, wherein the air outlet duct is configured such that an acoustic signal generated by the centrifugal fan assembly will impinge on at least one sidewall of the air outlet duct.
Example 8: The centrifugal fan system of any preceding example, wherein the housing forms a wall between the centrifugal fan assembly and the air outlet duct.
Example 9: The centrifugal fan system of example 8, wherein the air outlet duct extends along the wall.
Example 10: The centrifugal fan system of example 8 or 9, wherein the wall is disposed between fins of the centrifugal fan assembly and the air outlet duct.
Example 11: The centrifugal fan system of any of examples 8-10, wherein the wall extends to the air exhaust outlet.
Example 12: The centrifugal fan system of any preceding example, wherein the air outlet duct includes: a curved portion in airflow communication with the fan air duct; and a straight portion in airflow communication with the curved portion and the air exhaust outlet.
Example 13: The centrifugal fan system of example 12, wherein the curved portion includes a 90 degree bend.
Example 14: The centrifugal fan system of any preceding example, wherein the housing is formed of two components.
Example 15: The centrifugal fan system of any preceding example, wherein the housing includes: a fan housing portion that at least partially surrounds the centrifugal fan assembly and forms the fan air duct; and an air outlet housing portion that forms the air outlet duct.
Example 16: The centrifugal fan system of example 15, wherein the air outlet housing portion is formed as a separate structure from the fan housing portion and attached to the fan housing portion.
Example 17: A server comprising: a centrifugal fan system including: a centrifugal fan assembly; and a housing: attached to a portion of the server; at least partially surrounding the centrifugal fan assembly; forming a fan air duct in airflow communication with the centrifugal fan assembly; and forming an air outlet duct: in airflow communication with the fan air duct; including an air exhaust outlet configured to exhaust air from the server; and configured such that airflow from the fan air duct to the air exhaust outlet is non-linear.
Example 18: The server of example 17, wherein the air outlet duct includes: a curved portion proximate the fan air duct; and a straight portion in airflow communication with the curved portion and the air exhaust outlet.
Example 19: The server of example 18, wherein the curved portion includes a 90 degree bend.
Example 20: The server of any of examples 17-19, wherein the centrifugal fan system includes an acoustic material disposed on a sidewall of the air outlet duct that is configured to cancel, absorb, or reflect noise generated by the centrifugal fan assembly.
Example 21: A centrifugal fan system for exhausting air from a server, the centrifugal fan system comprising: a fan assembly; a fan housing comprising a fan air duct disposed in airflow communication with the fan assembly; and an air outlet housing comprising an air outlet duct disposed in airflow communication with the fan air duct and comprising an air exhaust outlet that is configured to exhaust air from the server, wherein the air outlet housing is configured such that airflow from the fan air duct to the air exhaust outlet via the air outlet duct is non-linear.
Example 22: The centrifugal fan system of example 21, wherein a sidewall of the air outlet housing comprises an acoustic material that is configured to inhibit noise generated by the fan assembly from exiting the air exhaust outlet
Example 23: The centrifugal fan system of example 22, wherein the acoustic material is configured to absorb noise from the fan assembly in at least one frequency.
Example 24: The centrifugal fan system of example 22 or 23, wherein the acoustic material comprises at least one of a foam-based material, a fiber-based material, and a paint-based material.
Example 25: The centrifugal fan system of example 22 or 23, wherein the acoustic material comprises a 3D printed material.
Example 26: The centrifugal fan system of example 20 or 21 or 22 or 23 or 24 or 25, wherein the acoustic material comprises an acoustic shape including at least one of a pyramid shape, a wedge shape and an egg-crate shape.
Example 27: The centrifugal fan system of example 20 or 21 or 22 or 23 or 24 or 25 or 26, wherein the air outlet duct is configured such that an acoustic signal from fan assembly will impact at least one sidewall of air outlet duct before exiting through air exhaust opening.
Example 28: The centrifugal fan system of example 20 or 21 or 22 or 23 or 24 or 25 or 26 or 27, wherein the air outlet duct extends alongside an exterior wall of the fan housing such that a portion of the fan housing is disposed between the fan assembly and the air exhaust opening.
Example 29: The centrifugal fan system of example 20 or 21 or 22 or 23 or 24 or 25 or 26 or 27 or 28, wherein the portion of the fan housing is disposed between fins of the fan assembly and the air exhaust opening.
Example 30: The centrifugal fan system of example 20 or 21 or 22 or 23 or 24 or 25 or 26 or 27 or 28 or 29, wherein the fan housing is disposed between the fan assembly and an entirety of the air exhaust opening.
Example 31: An apparatus for a server, the apparatus comprising: a fan assembly; a fan housing comprising a fan air duct disposed in airflow communication with the fan assembly; and an air outlet housing comprising an air outlet duct disposed in airflow communication with the fan air duct and comprising an air exhaust outlet that is configured to exhaust air from the server, wherein the air outlet housing is configured such that airflow from the fan air duct to the air exhaust outlet via the air outlet duct is non-linear.
Example 32: The apparatus of example 31, wherein a sidewall of the air outlet housing comprises an acoustic material that is configured to inhibit noise generated by the fan assembly from exiting the air exhaust outlet.
Example 33: The apparatus of example 32, wherein the acoustic material is configured to absorb noise from the fan assembly in at least one frequency.
Example 34: The apparatus of example 32 or 33, wherein the acoustic material comprises at least one of a foam-based material, a fiber-based material, and a paint-based material.
Example 35: The apparatus of example 32 or 33, wherein the acoustic material comprises a 3D printed material.
Example 36: The apparatus of example 32 or 33, wherein the acoustic material comprises an acoustic shape including at least one of a pyramid shape, a wedge shape and an egg-crate shape.
Example 37: The apparatus of example 31 or 32 or 33 or 34 or 35 or 36, wherein the air outlet duct is configured such that an acoustic signal from fan assembly will impact at least one sidewall of air outlet duct before exiting through air exhaust opening.
Example 38: The apparatus of example 31 or 32 or 33 or 34 or 35 or 36 or 37, wherein the air outlet duct extends alongside an exterior wall of the fan housing such that a portion of the fan housing is disposed between the fan assembly and the air exhaust opening.
Example 39: The apparatus of example 38, wherein the fan housing is disposed between the fan assembly and an entirety of the air exhaust opening.
Example 40: A system comprising: a server; and a centrifugal fan system, the centrifugal fan system comprising: a fan assembly; a fan housing comprising a fan air duct disposed in airflow communication with the fan assembly; and an air outlet housing comprising an air outlet duct disposed in airflow communication with the fan air duct and comprising an air exhaust outlet that is configured to exhaust air from the server, wherein the air outlet housing is configured such that airflow from the fan air duct to the air exhaust outlet via the air outlet duct is non-linear.
Example 41: A method to reduce air flow noise in a server, comprising: providing a server and a centrifugal fan system, the centrifugal fan system including a centrifugal fan assembly and a housing attached to a portion of the server and at least partially surrounding the centrifugal fan assembly, wherein the housing includes a fan air duct in airflow communication with the centrifugal fan assembly and an air outlet duct in airflow communication with the fan air duct, wherein the air outlet duct includes an air exhaust outlet configured to exhaust air from the server, and wherein the air outlet duct is configured such that airflow from the fan air duct to the air exhaust outlet is non-linear; energizing the centrifugal system, said energizing causing fins of the centrifugal fan system to impel air into and through the centrifugal fan system; and reducing air flow noise when at least part of an acoustic signal generated by the centrifugal fan assembly impinges on an acoustic material arranged on at least one sidewall of the air outlet duct.
Example 42: The method of claim 19, further comprising: detaching the fan air duct from the housing.

### CONCLUSION

The terminology used herein is for the purpose of describing particular embodiments only and is not intended to be limiting of this disclosure. As used herein, the singular forms “a”, “an” and “the” are intended to include the plural forms as well, unless the context clearly indicates otherwise. It will be further understood that the terms “includes”, “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, the terms up, upper, down, lower, above, below, left, right, forward, rearward, and the like are intended to be understood in the context of the representations described and illustrated above so that a wearable device may have such an orientation in reference to the frame or to various elements as supported by the frame or as illustrated in the drawing figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description, but is not intended to be exhaustive or limited to this disclosure in the form disclosed. Many modifications and variations will be apparent to those of ordinary skill in the art without departing from the scope and spirit of this disclosure. The various embodiments were chosen and described in order to best explain the principles of this disclosure and the practical application, and to enable others of ordinary skill in the art to understand this disclosure for various embodiments with various modifications as are suited to the particular use contemplated.

What is claimed is:

1. A system comprising:
a server; and
a centrifugal fan system including:
a centrifugal fan assembly; and
a housing attached to a portion of the server and at least partially surrounding the centrifugal fan assembly,
wherein the housing forms:
a fan air duct in airflow communication with the centrifugal fan assembly; and
an air outlet duct in airflow communication with the fan air duct,
wherein the air outlet duct includes an air exhaust outlet configured to exhaust air from the server, and
wherein the air outlet duct is configured such that airflow from the fan air duct to the air exhaust outlet is non-linear.

2. The system of claim 1, wherein the air outlet duct includes:
a curved portion proximate the fan air duct; and
a straight portion in airflow communication with the curved portion and the air exhaust outlet.

3. The system of claim 2, wherein the curved portion includes a 90 degree bend.

4. The system of claim 1, wherein the centrifugal fan system includes an acoustic material disposed on a sidewall of the air outlet duct that is configured to cancel, absorb, or reflect noise generated by the centrifugal fan assembly.

5. A centrifugal fan structure arranged for use with a centrifugal fan system, the centrifugal fan structure comprising:
a housing at least partially surrounding a centrifugal fan assembly,
wherein the housing forms:
a fan air duct in airflow communication with the centrifugal fan assembly; and
an air outlet duct in airflow communication with the fan air duct, the air outlet duct having at least one sidewall, wherein the air outlet duct is configured such that an acoustic signal generated by the centrifugal fan assembly will impinge on the at least one sidewall of the air outlet duct; and
an acoustic material arranged on the at least one sidewall, the acoustic material configured to mitigate noise generated by the centrifugal fan assembly,
wherein the air outlet duct includes an air exhaust outlet configured to exhaust air from the centrifugal fan structure, and
wherein the air outlet duct is configured such that airflow from the fan air duct to the air exhaust outlet is non-linear.

6. The centrifugal fan structure of claim 5, wherein the acoustic material is configured to mitigate noise having one or more frequencies.

7. The centrifugal fan structure of claim 5, wherein the acoustic material includes: a foam material, a fiber material, or a paint material.

8. The centrifugal fan structure of claim 5, wherein at least a portion of the acoustic material is formed via 3D printing.

9. The centrifugal fan structure of claim 5, wherein at least a portion of the acoustic material is formed as: a pyramid shape, a wedge shape, or an egg-crate shape.

10. The centrifugal fan structure of claim 5, wherein the housing forms a wall between the centrifugal fan assembly and the air outlet duct.

11. The centrifugal fan structure of claim 10, wherein the air outlet duct extends along the wall.

12. The centrifugal fan structure of claim 10, wherein the wall is disposed between fins of the centrifugal fan assembly and the air outlet duct.

13. The centrifugal fan structure of claim 10, wherein the wall extends to the air exhaust outlet.

14. The centrifugal fan structure of claim 5, wherein the air outlet duct includes:
a curved portion in airflow communication with the fan air duct; and
a straight portion in airflow communication with the curved portion and the air exhaust outlet.

15. The centrifugal fan structure of claim 14, wherein the curved portion includes a 90 degree bend.

16. The centrifugal fan structure of claim 5, wherein the housing is formed of at least two components.

17. The centrifugal fan structure of claim 5, wherein the housing includes:
a fan housing portion that at least partially surrounds the centrifugal fan assembly and forms the fan air duct; and
an air outlet housing portion that forms the air outlet duct.

18. The centrifugal fan structure of claim 17, wherein the air outlet housing portion is formed as a separate structure from the fan housing portion and attached to the fan housing portion.

19. A method to reduce air flow noise in a server, comprising:
providing a server and a centrifugal fan system, the centrifugal fan system including a centrifugal fan assembly and a housing attached to a portion of the server and at least partially surrounding the centrifugal fan assembly, wherein the housing includes a fan air duct in airflow communication with the centrifugal fan assembly and an air outlet duct in airflow communication with the fan air duct, wherein the air outlet duct includes an air exhaust outlet configured to exhaust air from the server, and wherein the air outlet duct is configured such that airflow from the fan air duct to the air exhaust outlet is non-linear;
energizing the centrifugal fan system, said energizing causing fins of the centrifugal fan system to impel air into and through the centrifugal fan system; and
reducing air flow noise when at least part of an acoustic signal generated by the centrifugal fan assembly impinges on an acoustic material arranged on at least one sidewall of the air outlet duct.

20. The method of claim 19, further comprising:
detaching the fan air duct from the housing.
